(19) United States
(12) Patent Application Publication
(10) Pub. No.: US 2016/0087185 A1
(43) Pub. Date: Mar. 24, 2016

(54) METHODS TO IMPROVE THE MECHANICAL PERFORMANCE OF ELECTROCALORIC POLYMERS IN ELECTROCALORIC REFRIGERATORS

(71) Applicant: Nascent Devices LLC, State College, PA (US)

(72) Inventor: Ailan CHENG, State College, PA (US)

(21) Appl. No.: 14/800,477

(22) Filed: Jul. 15, 2015

Related U.S. Application Data
(60) Provisional application No. 62/052,205, filed on Sep. 18, 2014.

(51) Int. Cl. H01L 37/02; F25B 21/00

(52) U.S. Cl. CPC H01L 37/025; F25B 21/00

(57) ABSTRACT

A cooling device utilizing the polymer composite materials possessing high electrocaloric effect and high elastic modulus are disclosed. Especially methods to enhance mechanical properties and reduce creep of the polymer composites with insulation fibers of high elastic modulus while maintain high electrocaloric effect.

### CROSS-REFERENCE TO RELATED APPLICATION

This application claims the benefit of U.S. Provisional Application No. 62/052,205 filed Sep. 18, 2014 the entire disclosure of which is hereby incorporated by reference herein.

### FIELD OF THE INVENTION

The present disclosure is directed to cooling devices employing electrocaloric (EC) polymer composites. In particular, the present disclosure relates to methods to enhance the mechanical properties and reduce creep of the EC polymers by forming composites that include EC fluoropolymers with insulation fibers.

### DISCUSSION OF THE BACKGROUND

Electrocaloric effect provides an attractive means to realize high efficiency and environmentally friendly cooling technology, particularly if the EC effect is large. Electrocaloric effect (ECE) is a result of direct coupling between the thermal properties such as entropy and temperature and electric properties such as electric field and polarization in an insulation dielectric material, in which a change in the applied electric field induces a corresponding change in polarization, which in turn causes a change in the dipolar entropy as measured by the isothermal entropy change ΔS in the dielectrics (entropy change is related to the heat Q=T ΔS, where T is the temperature). If the electric field change is carried out in an adiabatic condition, the dielectric will experience an adiabatic temperature change ΔT. However, materials with small ECE (ΔT<2 K) near room temperature reported in the past makes it unpractical for cooling devices. Recently, it was discovered that in a class of polar-dielectric polymers, a very high electrocaloric effect (ECE), i.e., a ΔT>10 K under electric fields of 140 MV/m or lower, can be achieved (Neese, et al., Large Electrocaloric Effect in Ferroelectric Polymers Near Room Temperature. Science, 321, 821-823 (2008); Lu, et al., Organic and Inorganic Relaxor Ferroelectrics with Giant Electrocaloric Effect, Appl. Phys. Lett. 97, 162904 (2010); Li, et al., Tunable Temperature Dependence of Electrocaloric Effect in Ferroelectric Relaxor P(VDF-TrFE-CFE) Terpolymer, Appl. Phys. Lett. 99, 052907 (2011)).

EC polymers are useful as solid state refrigerants for refrigeration devices and heat pumps. In such devices, EC polymers can be arranged in a multilayer module, referred to as an EC module. However, a general feature of operating refrigeration devices or heat pumps is that the EC modules will experience forces across the entire volume which may not be uniform. These forces can cause deformation (EC polymer modules change shapes at different locations) and creep (slow shape changes which become permanent even after the removal of the forces) of the EC polymer modules which reduces the cooling device's performance and can lead to permanent damage or even failure of the EC polymer modules. Hence a need exists to reduce deformation and creep experienced by EC modules in EC cooling devices.

### SUMMARY OF THE INVENTION

Advantages of the present disclosure include cooling devices, such as air conditioning, refrigeration, and heat pumps, comprising EC fluoropolymer composites. Such EC fluoropolymer composites can include EC fluoropolymers with insulation fibers. Advantageously, the insulating fibers can enhance the elastic properties such as the elastic modulus and tensile strength of the EC fluoropolymer composites and reduce creep without substantially reducing the electrocaloric response of the EC fluoropolymer.

These and other advantages are satisfied, in part, by a cooling device comprising a refrigerant which includes an electrocaloric (EC) fluoropolymer composite. Advantageously, the EC fluoropolymer composite has an elastic modulus higher than 0.5 GPa. Such a cooling device can transfer heat from cold end (lower temperature) to hot end (higher temperature), or vice versa, by employing the EC fluoropolymer composite. The cooling device can further include an electric field or voltage generator to apply a cyclic electric field or voltage to the EC fluoropolymer composite to induce a cyclic temperature change (i.e., increase and decrease) through the electrocaloric effect.

Embodiments of the present disclosure include one or more of the following features individually or combined. For example, the EC fluoropolymer composite can have an elastic modulus, along one direction, higher than 0.5 GPa in the temperature range from −10° C. to 50° C. In some embodiments, the EC fluoropolymer composite can have an electric field induce temperature change, in the adiabatic condition, of more than 6° C. (heating 6° C. upon application of electric field and cooling of 6° C. upon removing of electric field), under an electric field not higher than 100 MV/m, for example. In other embodiments, the EC fluoropolymer composite can have dielectric breakdown field higher than 200 MV/m as a film of the EC fluoropolymer composite. In still further embodiments, the EC fluoropolymer composite can additionally include EC ceramics, and high thermal conductivity (>50 W/mK) nano-fibers/sheets/tubes.

The EC fluoropolymers can have a dielectric constant higher than 10, e.g., higher than 15, at room temperature. In some embodiments, the EC fluoropolymer composite can include a blend of EC fluoropolymers, e.g., EC fluoropolymers having a dielectric constant higher than 10 at room temperature.

In other embodiments, the EC fluoropolymer composites can comprise EC fluoropolymers exhibiting significant ECE. Examples of EC fluoropolymers useful for the EC fluoropolymer composites include one or more of terfluoropolymers, cofluoropolymers, mixtures and blends thereof. The terfluoropolymers can have the formula of: P(VDF_{1-x-y}-R¹ₓ—R²_{y}), where VDF is vinylidene fluoride, R¹ can be trifluoroethylene (TrFE) and/or tetrafluoroethylene (TFE), and R² can be chlorofluoroethylene (CFE), chlorotrifluoroethylene (CTFE), chlorodifluoroethylene (CDFE), hexafluoropropylene (HFP), hexafluoroethylene (HFE), vinylidene chloride (VDC), vinyl fluoride (VF), TFE and combinations thereof, where x is in a range of 0.25 to 0.49, and y is in a range from 0.03 to 0.2, for example. Such EC fluoropolymers include but are not limited to neat terpolymers such as terpolymers of P(VDF_{1-x-y}-TrFEₓ-CFE_{y}), P(VDF_{1-x-y}-TrFEₓ-CTFE_{y}), P(VDF_{1-x-y}-TFEₓ-CTFE_{y}), and P(VDF_{1-x-y}-TFEₓ-CFE_{y}), for example. The copolymer can be selected from the group consisting of P(VDF_{1-z}-CTFE_{z}), P(VDF_{1-z}TFE_{z}), P(VDF_{1-z}-TrFE_{z}) wherein z is in a range of 0<z≦0.49, and mixture thereof and blends thereof, for example. The EC fluoropolymers composite can also include blends of the terfluoropolymers with the cofluoropolymers such as copolymers of P(VDF_{1-z}-R³_{z}) and P(VF_{1-z}-R³_{z}), where z is in a range of 0<z≦0.49 and R³ is TrFE, TFE, CTFE, HFP, CFE and mixtures thereof.

The insulation fibers can be inorganic or organic and can have elastic modulus higher than 20 GPa and an aspect ratio (length/diameter) higher than 100. In some embodiments, the insulation fibers are any one of glass fibers, alumina fibers, boron nitride (BN), polyethylene highly oriented fibers (PE), and Kevlar fibers, for example. Examples of fibers of the present disclosure include the micron-sized fibers (diameters in microns) with high aspect ratio (length/diameter>100). In other embodiments, the insulation fibers can have a diameter larger than 0.2 micron and are substantially aligned with each other. Such alignment advantageously can enhance the elastic modulus of the composite along the fiber length direction and can the elastic modulus of the composite along the composite film surface directions.

Additional examples of the present disclosure include composite materials comprised of (1) one or more EC fluoropolymers, (2) one or more EC ceramic nano-particles and/or (3) insulation fibers, e.g., fibers having high elastic modulus yet electrically insulating. In such an embodiment, the EC polymer with EC ceramic nano-particles form a EC polymer matrix with the insulation fibers to enhance mechanical properties of the composite.

Useful fillers include inorganic or organic fillers having high elastic modulus (>20 GPa) and fibers of Al₂O₃, boron nitride (BN), polyethylene highly oriented fibers (PE), glass fibers, and Kevlar fibers.

Additional advantages of the present invention will become readily apparent to those skilled in this art from the following detailed description, wherein only the preferred embodiment of the invention is shown and described, simply by way of illustration of the best mode contemplated of carrying out the invention. As will be realized, the invention is capable of other and different embodiments, and its several details are capable of modifications in various obvious respects, all without departing from the invention. Accordingly, drawings and descriptions are to be regarded as illustrative in nature, and not as restrictive.

### BRIEF DESCRIPTION OF THE DRAWINGS

Reference is made to the attached drawings, wherein elements having the same reference numeral designations represent similar elements throughout. The features of the present disclosure and appended claims, taken in conjunction with the drawings. Understanding that these drawings describe only several embodiments of the disclosure and are, therefore, not to be considered limiting of its scope and wherein:

FIGS. 1(a) and 1(b) illustrate an EC polymer module and assembly. FIG. 1(a) schematically shows EC polymer module with EC polymers in a multilayer configuration; FIG. 1(b) shows the EC polymer modules arranged in parallel in an assembly with channels for heat exchange fluids are pumped through the channels formed by these EC polymer modules.

FIG. 2. is a schematic of an EC refrigerator, which has EC polymer modules and a bi-directional pump to flow heat exchange fluid, in synchronicity with applied fields, to generate cooling (or heating).

FIG. 3. is a schematic of an EC refrigerator, comprising of many EC ring pair in which the two EC rings rotate in opposite directions and with pattered electrodes.

FIGS. 4(a), 4(b) and 4(c) illustrate various EC fluoropolymer composites. FIG. 4(a) is a schematic drawing of an EC polymer/high elastic modulus fiber composite in which the fibers are aligned preferably along one direction throughout the whole film (very long fibers); FIG. 4(b) is a schematic drawing of an EC polymer/high elastic modulus fiber composite in which the fibers are aligned along one direction, and the fiber length is shorter than the film length; FIG. 4(c) is a schematic drawing of an EC polymer/high elastic modulus fiber composite in which fibers are preferably in parallel to the film surfaces, and random in the surface. In these composites, the fibers of high elastic modulus and diameter from below 1 micron to several microns and have a high aspect (length/diameter) ratio (>100).

### DETAILED DESCRIPTION OF THE DISCLOSURE

The present disclosure is directed to electrocaloric cooling devices, including but not limited to, heat pumps, refrigerators, air conditioning, climate control systems, to transfer heat from at load at one temperature T₁ to another temperature heat sink T₂ (T₂>T₁ for refrigerators and T₁>T₂ for heat pumps). The cooling devices of the present disclosure include at least one electrocaloric fluoropolymer composite as a refrigerant. Such composites can have a high elastic modulus (>0.5 GPa) and preferably along at least one direction with high electrocaloric effect (ECE). Advantageously, the electrocaloric polymer composite exhibits a significant temperature/entropy change upon the application and removal of electric field or voltage. Such EC fluorpolymer composites include one or more EC fluoropolymers having high elastic modulus and one or more type of insulation fibers, which have an aspect ratio.

The following detailed description is made to the drawings. In the drawings similar symbols typically identifying similar components unless context denotes otherwise. The illustrative embodiments described in detailed description, drawings, and claims are not meant to be limiting. Other embodiments and modifications are also within the scope of the present disclosure.

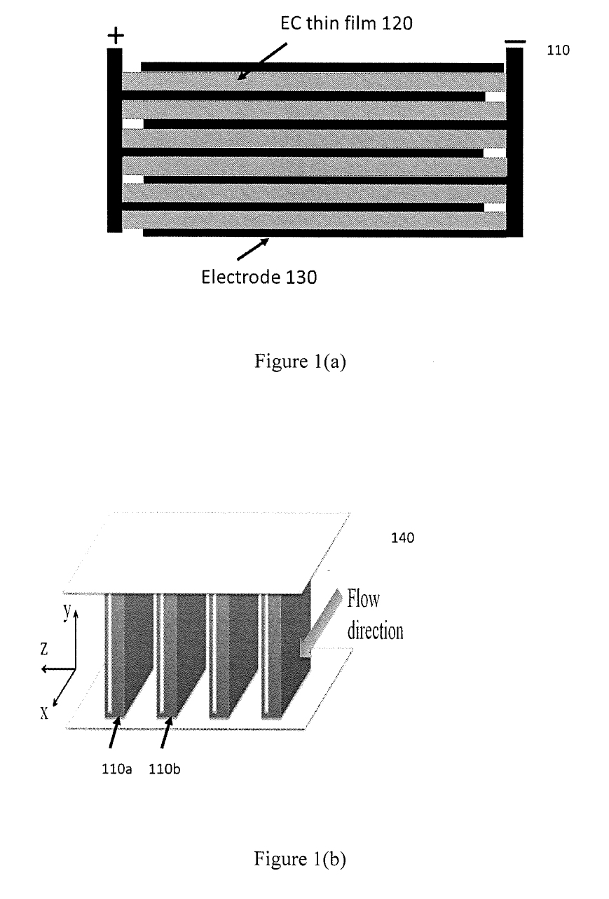

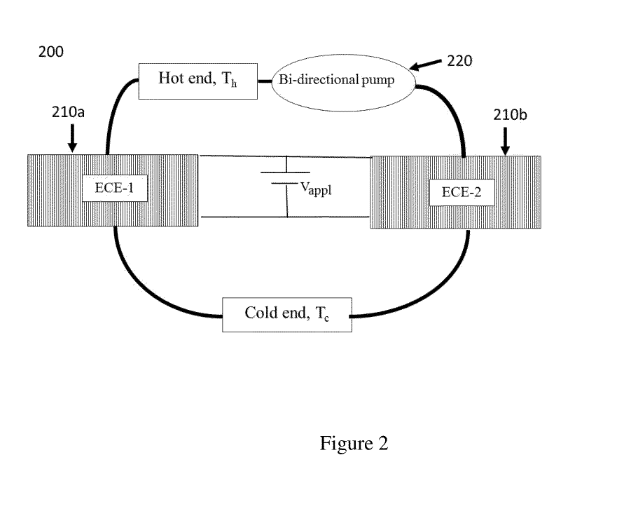

FIGS. 1 and 2 schematically illustrate how EC modules can experience deformation forces during the operation of the device. In cooling devices, the EC polymers can be employed in a multilayer configuration. For example and as illustrated in FIG. 1(a), multilayered EC polymer (also referred to as an EC polymer module) 110 includes several layers of EC polymer as thin films 120 with electrodes 130 therebetween. In many EC refrigeration devices and heat pumps, these EC polymer modules are held at the two ends and arranged to form parallel array, see FIG. 1(b) which illustrates a series of EC polymer modules 110a, 110b, etc. arranged in parallel having channels 140 for the flow of fluids formed by the EC polymer modules. The flow of fluids can be synchronized with the change of the applied electric fields on the EC modules.

FIG. 2 illustrates an EC refrigerator, which has EC polymer modules 210a, 210b with fluid channels and bi-directional pump 220 to exchange fluid between the modules 210a and 210b to transport the heat from the cold (T_{c}) end to the hot end (Tₕ), achieving cooling or vice versa. EC polymer modules 210a and 210b can be configured as shown in FIG. 1(b).

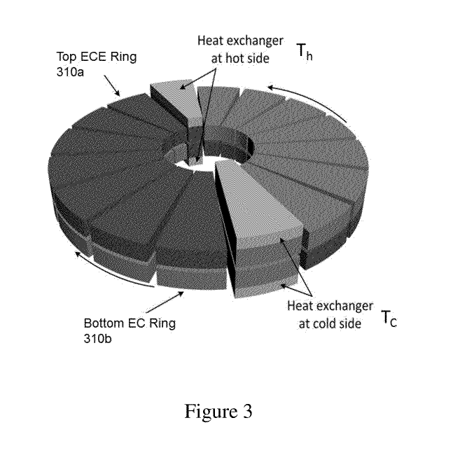

In another refrigeration device configuration, FIG. 3, EC modules 310a can be configured to form a top ring and EC modules 310b can be configured to form a bottom ring. During operation, top and bottom EC rings are rotated in opposite directions relative to each other and in that process, pump heat from the cold end (T_{c}) to hot end (Tₕ), e.g., refrigeration, or vice versa (heat pump). In these devices, the EC modules are held at the two ends while experiencing mechanical forces in the entire module volume during the device operation as the fluid moves through the channels in FIG. 2 or the direct contacting forces between the mating surfaces in FIG. 3.

As explained in the background section, a general feature of operating refrigeration devices or heat pumps is that EC modules will experience forces across the entire volume which may not be uniform. These forces can cause deformation (EC polymer modules change shapes at different locations) and creep (slow shape changes which become permanent even after the removal of the forces) of the EC polymer modules which reduces the cooling device performance and can lead to permanent damage or even failure of the EC polymer modules. These problems can be reduced by enhancing the elastic modulus of the EC polymer modules to make them stronger (less deformation under external stresses) by forming composites with fibers of high elastic modulus (>20 GPa) while maintaining high EC responses.

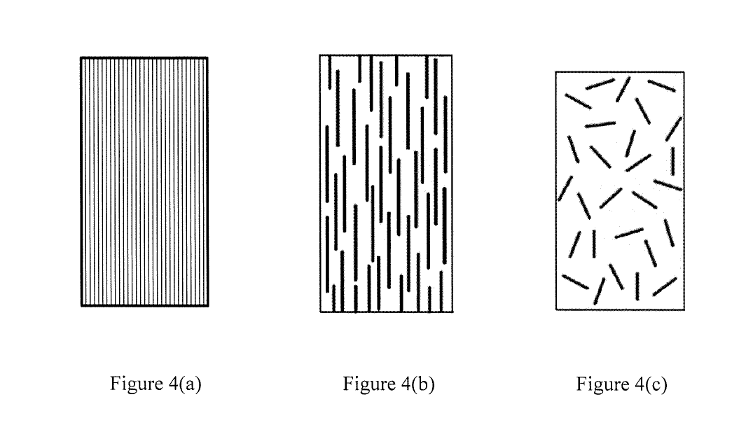

For example, by including small volume fraction of fibers of high elastic modulus in the EC polymer modules, as illustrated in FIGS. 4(a) through 4(c), the elastic modulus can be improved and the EC polymer modules can be made much stronger so that to reduce the creep under external stresses. FIG. 4(a) illustrates a composite configuration in which all the long fibers, such as glass fibers or Al₂O₃ fibers or Kevlar fibers, which are very strong materials (show very little deformation and creep under stresses) and possess much higher elastic modulus, >20 GPa, preferably >40 GPa, (in general the elastic modulus of EC polymer near room temperature is less than 0.3 GPa) and whose diameter is smaller than the EC film thickness in the EC multilayer modules, are aligned along one direction which improves the elastic modulus of the EC polymer modulus and yield strength, and reduce creep of the EC polymer modules along the same direction. As an example, the long fiber/EC polymer composites of FIG. 4(a) can be fabricated by solution casting method in which the long fibers are arranged in parallel and then an EC polymer solution is poured to the aligned fibers. By evaporating the solvent, a fiber/EC polymer composite film of FIG. 4(a) can be formed. Other fibers can also be used including boron nitride (BN), and polyethylene highly oriented fibers (PE), and insulation fibers having elastic modulus>20 GPa can be used.

In the configuration of FIG. 4(b), the fibers, which are a few micrometer in diameter (thinner than the EC film thickness) and have an aspect ratio (length/diameter) larger than 100, for example, are included in composites with their long fiber axis preferably aligned a single direction and in parallel to the composite film surface which enhance the elastic modulus and yield strength and reduce creep along the same direction markedly. The fiber/EC polymer composite films can be fabricated using the tape casting method. In the fabrication process, the high elastic modulus fibers with a pre-determined amount (determined by the total volume fraction of the fibers in the EC composite) are mixed with the EC fluoropolymer solution, the solution can be tape casted through doctor blade, which causes preferred fiber long axis orientation along the composite film surface and the film casting direction (the direction of relative motion between the substrate and doctor blade. The fiber/EC fluoropolymer composite film is formed after the evaporation of the solvent. Melt extrusion method can also be employed to fabricate the fiber/EC polymer composite films.

In the configuration of FIG. 4(c), the fibers, which are a few micrometer in diameter (thinner than the EC film thickness) and have an aspect ratio (length/diameter) larger than 100, for example, are included in composites with their long fiber axis preferably aligned in parallel to the composite film surfaces which enhance the elastic modulus and yield strength and reduce creep along (parallel to) the film surface markedly.

In these high elastic modulus fiber/EC fluoropolymer composites, the fibers do not possess electrocaloric effect and consequently including them in the composites may cause reduction of the EC response. Therefore, the volume fraction of the fibers in the composites should be low, e.g., below 10% in volume and preferably below 5% in volume. In addition, to maintain a high electric breakdown strength, these fibers should be highly electrically insulating. Glass fibers, Al₂O₃ (alumina) fibers, boron nitride (BN), polyethylene highly oriented fibers (PE) and Kevlar fibers, and insulation fibers of high elastic modulus (>20 GPa) are examples that meet these requirements. In general, the elastic modulus of EC polymer such as blends composed of 90% P(VDF-TrFE-CFE) relaxor terpolymer/10% P(VDF-TrFE) normal ferroelectric copolymer is lower than 0.3 GPa. Hence, the elastic modulus of these insulation fibers is much higher than that of the EC polymers:

The relative modulus of some fibers are: Glass-fibers>70 GPa, Kevlar fibers>70 GPa, and Al₂O₃ fibers>370 GPa.

Table 1 below provides experimental data of enhanced elastic modulus of EC polymer films, which are P(VDF-TrFE-CFE) terpolymer/P(VDF-TrFE) copolymer blends, and composites with 5 vol % and 10 vol % of alumina fibers of diameter in 0.2 μm to 0.4 μm and length in the range of 100 μm to 1000 μm. The films were fabricated using solution cast method and the fiber alignment in the composites is similar to that in FIG. 4(c).

TABLE 1

| Films | Elastic modulus (GPa) | |
|---|---|---|
| Blend | 0.2 | GPa |
| Composite-5 | 0.71 | G |
| Composite-10 | 1.14 | G |

The elastic modulus of an EC blend of P(VDF-TrFE-CFE) terpolymer with 10 wt % of P(VDF-TrFE) 65/35 mol % copolymer (Blend); the blend composites with 5 vol % of Al₂O₃ fibers (0.2 μm to 0.4 μm diameter and length in the range of 100 μm to 1000 μm) (Composite-5 and Composite-10). The elastic modulus was measured at room temperature and 1 Hz.

The fibers have preferred orientation with their long axis along the film surface in the composites. The fiber/EC polymer composite films were fabricated by first dissolving the EC polymer in a solvent such as DMA (N,N-dimethylformamide) and then adding Al₂O₃ fiber in the solution (the amount is determined by the vol % of the fiber in the composite). The solution after sonication to disperse the fibers in the solution was casted on a substrate and dried to form a composite film. As can be seen, even in this case, the fibers have random orientations along (in parallel to) the film surface directions, there is a significant enhancement in the elastic modulus, even with 5 vol % of Alumina fibers.

By aligning the fibers along one direction (FIG. 4(a)), the elastic modulus along the alignment direction can be enhanced much more. This can be derived from the elastic properties of composites, and the elastic modulus Y_{c} of the composite FIG. 4(a) is

Y_{c}=f_{fib}Y_{fib}f_{EC}Y_{EC} (1)

where f_{fib} and f_{EC} are the volume fractions of the fiber and EC polymer in the composite, and Y_{fib} and Y_{EC} are the elastic moduli of the two components. Y_{EC}=0.3 GPa and Y_{fib}=70 GPa, a 5 vol % of fibers in the composite FIG. 4(a) can lead to an Yc=3.8 GPa, a more than 12 times increase in the elastic modulus. Moreover, the long fibers (such as glass fibers) in FIG. 4(a) do not have the creep (very high tensile strength) problem when subject to external stress and hence can significantly improve the mechanical properties of the EC fluoropolymer modules.

For example, the EC fluoropolymer composite can have an elastic modulus, along one direction, higher than 0.5 GPa in the temperature range from −10° C. to 50° C. In some embodiments, the EC fluoropolymer composite can have an elastic modulus, along at least one direction, larger than 1 GPa in the temperature range from −10° C. to 70° C., e.g., an elastic modulus, along at least one direction, larger than 2 GPa in the temperature range from −20° C. to 90° C.

The EC polymers include but are not limited to the neat terfluorpolymers P(VDF_{1-x-y}-TrFEₓ-CFE_{y}), P(VDF_{1-x-y}-TrFEₓ-CTFE_{y}), P(VDF_{1-x-y}-TrFEₓ-HFP_{y}), P(VDF_{1-x-y}-TFEₓ-CTFE_{y}), and P(VDF_{1-x-y}-TFEₓ-CFE_{y}) (0.25≦x≦0.49 and 0.03≦y≦0.2) which exhibit significant EC responses.

The EC polymers also include the blends of these terpolymers with copolymers P(VDF_{1-z}-TrFE_{z}) and P(VDF_{1-z}-TFE_{z}), (0<z≦0.49) and/or P(VDF_{1-z}-CTFE_{z}), P(VDF_{1-z}-HFP_{z}) (e.g., 0<z<0.1). The EC polymer can be a blend of fluoropolymers. Such blends include at least one terfluoropolymer (e.g., poly(vinylidene fluoride-trifluoroethylene-chlorofluoroethylene) (P(VDF-TrFE-CFE)) and at least one cofluoropolymer (e.g., poly(vinylidene fluoride-trifluoroethylene) P(VDF-TrFE)).

The terfluoropolymers useful for the present disclosure and used in blends include: polyvinylidene fluoride-trifluoroethylene-chlorofluoroethylene (P(VDF-TrFE-CFE)), polyvinylidene fluoride-trifluoroethylene-chlorodifluoroethylene (P(VDF-TrFE-CDFE)), polyvinylidene fluoride-trifluoroethylene-chlorotrifluoroethylene (P(VDF-TrFE-CTFE)), polyvinylidene fluoride-trifluoroethylene-hexafluoropropylene (P(VDF-TrFE-HFP)), polyvinylidene fluoride-trifluoroethylene-tetrafluoroethylene (P(VDF-TrFE-TFE)), polyvinylidene fluoride-trifluoroethylene-vinylidene chloride P(VDF-TrFE-VDC), polyvinylidene fluoride-trifluoroethylene-vinyl fluoride P(VDF-TrFE-VF), polyvinylidene fluoride-trifluoroethylene-hexafluoroethylene P(VDF-TrFE-HFE), polyvinylidene fluoride-tetrafluoroethylene-chlorofluoroethylene (P(VDF-TFE-CFE)), polyvinylidene fluoride-tetrafluoroethylene-chlorodifluoroethylene (P(VDF-TFE-CDFE)), polyvinylidene fluoride-tetrafluoroethylene-chlorotrifluoroethylene (P(VDF-TFE-CTFE)), polyvinylidene fluoride-tetrafluoroethylene-hexafluoropropylene (P(VDF-TFE-HFP)), polyvinylidene fluoride-tetrafluoroethylene-hexafluoroethylene P(VDF-TFE-HFE), polyvinylidene fluoride-tetrafluoroethylene-vinylidene chloride P(VDF-TFE-VDC), polyvinylidene fluoride-tetrafluoroethylene-vinyl fluoride P(VDF-TFE-VF), and the mixture. These terpolymers have monomer units in ratios defined for the variables x and y provided in the various embodiments of the present disclosure.

Cofluorpolymers useful for the present disclosure and used in blends include: P(VDF_{1-z}-R³_{z}) and P(VF_{1-z}-R³_{z}), where z is in a range of 0<z≦0.49 and R³ is TrFE, TFE, CTFE, HFP, CFE and mixtures thereof. Such copolymers can be selected, for example, from P(VDF_{1-z}-CTFE_{z}), P(VDF_{1-z}-CFE_{z}), P(VDF_{1-z}-TrFE_{z}), P(VDF_{1-z}-TFE_{z}), P(VF_{1-z}-CTFE_{z}), P(VF_{1-z}-CFE_{z}), P(VF_{1-z}-HFP_{z}), P(VF_{1-z}-TrFE_{z}), and P(VF_{1-z}-TFE_{z}), wherein z is in a range of 0<z≦0.49.

The EC fluoropolymers can have a dielectric constant higher than 10, e.g., higher than 15, at room temperature. In some embodiments, the EC fluoropolymer composite can include a blend of EC fluoropolymers, e.g., EC fluoropolymers having a dielectric constant higher than 10 at room temperature.

Advantageously, the polymer blends exhibit an adiabatic temperature change of higher than 4° C. under 100 MV/m or lower electric field, e.g., greater than about 6, 8 or even an adiabatic temperature change of higher than 10° C. under 100 MV/m or lower electric field. Polymer blends comprising of at least one polymer selected from the terpolymer with chemical formula: P(VDF_{1-x-y}-R¹ₓ—R²_{y}), where R¹ is selected from trifluoroethylene (TrFE) and/or tetrafluoroethylene (TFE), and R² is selected from chlorofluoroethylene (CFE), chlorotrifluoroethylene (CTFE), chlorodifluoroethylene (CDFE), hexafluoropropylene (HFP), hexafluoroethylene (HFE), vinylidene chloride (VDC), vinyl fluoride (VF), TFE and combinations thereof. The variable x is in a range 0.25 to 0.49, and y is in a range of 0.03 to 0.2. The at least one copolymer can be selected from P(VDF_{1-z}-R³_{z}) and P(VF_{1-z}-R³_{z}), where z is in a range of 0<z≦0.49 and R³ is TrFE, TFE, CTFE, HFP, CFE and mixtures thereof. Such copolymers include, for example, P(VDF-CFE), P(VDF-CTFE), P(VDF-TFE), P(VDF-TrFE), P(VDF-HFP), and mixture thereof.

The weight ratio of the two polymers in the blends can range from 70 wt % of the ter-polymer/30 wt % copolymer to 97 wt % ter-polymer/3 wt % co-polymer. Preferably, the copolymer in the blend is less than 15 wt % based on the total weight of the ter-polymer and copolymer in the blend. In one embodiment, the blend comprises a blend of a P(VDF_{1-x-y}-TrFE_{y}-R²ₓ) terpolymer (0.25<x<0.49, 0.03<y<0.1) or a P(VDF_{1-x-y}-TFE_{y}-R²ₓ) terpolymer (0.25<x<0.49, 0.03<y<0.1) or a mixture thereof where R² is CTFE or CFE or HFP in combination with a P(VDF_{1-z}-TrFE_{z}) (e.g., 0<z≦0.49) or P(VDF_{1-z}-TFE_{z}) (e.g., 0<z<0.5), P(VDF_{1-z}-CTFE_{z}) (0<z<0.1), P(VDF_{1-z}-HFP_{z}) (e.g., 0<z<0.1) copolymer or a mixture thereafter and a weight percent of less than 15%. The polymer blends can exhibit a temperature change (adiabatic temperature change) of more than 5° C., induced under an electric field of 100 MV/m or lower, e.g., greater than about 6, 8 or even an adiabatic temperature change of higher than about 9° C. under 100 MV/m or lower electric field.

In a broad sense, the EC polymers can additionally include fluoropolymer-inorganic particles (including nano-tubes and nano-fibers) nano-composites, fluoropolymer-inorganic micron-sized fiber composites, fluoropolymer-high thermal conductivity polymer fibers composites. The fluoropolymer is selected from the neat terpolymers or polymer blends as have been described earlier. The inorganic particles or micron-sized fibers to be mixed with the fluoropolymers are selected from insulation nano-particles such as oxides and nitrides: Al₂O₃, AlN, BN, Si₃N₄, SiC, MgO, SiO₂, ZrO₂, TiO₂, HfO₂, Ta₂O₅, La₂O₃, and other similar nano-particles. We have shown that the P(VDF-TrFE-CFE) terpolymer and ZrO₂ or TiO₂ nano-particle composites can exhibit higher polarization level compared with the neat terpolymer under a fixed electric field if the nano-particle volume fraction is less than 5% (for ZrO₂) and 10% (for TiO₂). The inorganic nano-particles to be mixed with the fluoropolymer are selected from insulation nano-particles of ferroelectrics such as BaTiO₃, Ba(Ti₁₋ₓZrₓ)O₃ (x<0.3), Ba(Ti₁₋ₓSnₓ)O₃, (Ba₁₋ₓSrₓ)(Ti_{1-y}Zr_{y})O₃ (x<0.3, y<0.3), (Ba₁₋ₓSrₓ)TiO₃ (x<0.3) (Ba₁₋ₓSrₓ)(Ti_{1-y}Sn_{y})O₃, SrBiTa₂O₉, (Ba_{0.3}Na_{0.7})(Ti0_{0.3}Nb_{0.7})O₃, Na_{0.5}Bi_{0.5}TiO₃, (PbLa)(Zr₁₋ₓTiₓ)O₃, and (Pb(MgNb)O₃)₁₋ₓ—(PbTiO₃)ₓ.

Fabrication of the high elastic modulus EC fluorpolymer composites can be achieved by aligning micron-diameter fibers of high elastic modulus, casting a EC fluorpolymer solution onto the aligned fibers, and evaporating the solvent.

Fabrication of the high elastic modulus EC fluoropolymer composites can be achieved by dispersing high aspect ratio (>100) fibers of high elastic modulus in the EC fluoropolymer solution, tape casting the EC fluoropolymer solution with fibers on a substrate, and evaporating the solvent. The fibers thus fabricated will have preferred alignment along the casting direction in parallel to the composite film surface.

The present disclosure describes only the preferred embodiment and examples as illustration of the invention. Various alternatives and modifications can be devised by those skilled in the art without departing from the spirit and scope of the present disclosure. Accordingly, such alternatives and modifications are considered to be within the scope of this invention and are covered by the following claims.

1. A cooling device comprising a refrigerant which includes an electrocaloric (EC) fluoropolymer composite, wherein the EC fluoropolymer composite has an elastic modulus higher than 0.5 GPa.

2. The device of claim 1, wherein the EC fluoropolymer composite comprises one or more EC fluoropolymers having high elastic modulus and insulation fibers which have an aspect ratio higher than 100.

3. The device of claim 1, wherein the EC fluoropolymer composite has an elastic modulus, along one direction, higher than 0.5 GPa in the temperature range from −10° C. to 50° C.

4. The device of claim 1, wherein the EC fluoropolymer composite comprises one or more EC fluoropolymers and insulating fibers which have elastic modulus higher than 20 GPa and an aspect ratio higher than 100.

5. The device of claim 2, wherein the insulation fiber are any one of glass fibers, alumina fibers, boron nitride (BN), polyethylene highly oriented fibers (PE), and Kevlar fibers.

6. The device of claim 2, wherein the EC fluoropolymer composite has a volume fraction of the insulation fiber of less than 10 volume percent but higher than 1 volume percent.

7. The device of claim 1, wherein the EC fluoropolymer composite includes an EC fluoropolymer having a dielectric constant higher than 15 at room temperature.

8. The device of claim 7, wherein the EC fluoropolymer has the formula of: P(VDF_{1-x-y}-R¹ₓ—R²_{y}) alone or in combination with one or more of P(VDF_{1-z}-R³_{z}) and/or P(VF_{1-z}-R³_{z}), wherein VDF is vinylidene fluoride, R¹ is selected from trifluoroethylene (TrFE) and/or tetrafluoroethylene (TFE), R² is selected from chlorofluoroethylene (CFE), chlorotrifluoroethylene (CTFE), chlorodifluoroethylene (CDFE), hexafluoropropylene (HFP), hexafluoroethylene (HFE), vinylidene chloride (VDC), vinyl fluoride (VF), TFE and combinations thereof, R³ is TrFE, TFE, CTFE, HFP, CFE and combinations thereof, x is in a range of 0.25 to 0.49, y is in a range of 0.03 to 0.2 and z is in a range of 0<z<0.49.

9. The device of claim 8, wherein the EC fluoropolymer composite includes a blend of the EC fluoropolymer having a dielectric constant higher than 10 at room temperature.

10. The device of claim 9, wherein the blend comprises a blend of a P(VDF_{1-x-y}-TrFE_{y}-R²ₓ) terpolymer (0.25<x<0.49, 0.03<y<0.1) or a P(VDF_{1-x-y}-TFE_{y}-R²ₓ) terpolymer (0.03<x<0.1, y<0.49) or a mixture thereof where R² is CTFE or CFE or HFP in combination with a P(VDF_{1-z}-TrFE_{z}) or P(VDF_{1-z}-TFE_{z}), P(VDF_{1-z}-CTFE_{z}), P(VDF_{1-z}-HFP_{z}) copolymer or a mixture thereof and a weight percent of less than 15%.

11. The device of claim 1, wherein the EC fluoropolymer composite has an electric field induce temperature change, in the adiabatic condition, of more than 6° C., under an electric field not higher than 100 MV/m.

12. The device of claim 2, wherein the insulation fibers of high elastic modulus have a diameter larger than 0.2 micron and are substantially aligned with each other which enhance the elastic modulus of the composite along the fiber length direction.

13. The device of claim 1, wherein EC fluoropolymer composite comprises EC fluoropolymers, EC ceramics, and high thermal conductivity (>50 W/mK) nano-fibers/sheets/tubes.

14. The device of claim 1, wherein the EC fluoropolymer composite has dielectric breakdown field higher than 200 MV/m as a film of the EC fluoropolymer composite.
